(19) United States
(12) Patent Application Publication
(10) Pub. No.: US 2025/0015118 A1
(43) Pub. Date: Jan. 9, 2025

(54) LIGHT DETECTION APPARATUS AND ELECTRONIC APPARATUS

(71) Applicant: SONY SEMICONDUCTOR SOLUTIONS CORPORATION, Kanagawa (JP)

(72) Inventor: Yuta NISHIOKA, Kanagawa (JP)

(73) Assignee: SONY SEMICONDUCTOR SOLUTIONS CORPORATION, Kanagawa (JP)

(21) Appl. No.: 18/705,078

(22) PCT Filed: Sep. 15, 2022
(86) PCT No.: PCT/JP2022/034596

§ 371 Date: Apr. 26, 2024

(30) Foreign Application Priority Data
Nov. 4, 2021 (JP) 2021-180375

(51) Int. Cl. H01L 27/146

(52) U.S. Cl. CPC H01L 27/14636; H01L 27/14634

(57) ABSTRACT

A light detection apparatus is provided that makes it possible to prevent a reduction in a level of imaging properties. A second wiring layer is formed inside of a second semiconductor substrate. First wiring (wiring) and second wiring (wiring) are included in the second wiring layer, where the first wiring and the second wiring extend in parallel with a back surface (a first surface) of the second semiconductor substrate. Further, an insulator that insulates the first wiring and the second wiring from the second semiconductor substrate is included in the second wiring layer. Furthermore, the first wiring and second wiring in the second wiring layer are electrically connected to a drain (a specified portion) of a transistor (a connection target) formed in the back surface of the second semiconductor substrate.

### TECHNICAL FIELD

The present technology (The technology according to the present disclosure) relates to a light detection apparatus and an electronic apparatus.

### BACKGROUND ART

Conventionally, for example, a light detection apparatus that includes a sensor substrate including a plurality of arranged photoelectric converters, and a logic substrate stacked on the sensor substrate has been proposed (for example, refer to Patent Literature 1). The light detection apparatus disclosed in Patent Literature 1 includes a logic substrate including a semiconductor substrate on which a logic circuit is arranged, and a wiring layer formed on a surface of the semiconductor substrate that is situated on a side of the sensor substrate.

### CITATION LIST

### Patent Literature

Patent Literature 1: Japanese Patent Application Laid-open No. 2021-103792

### DISCLOSURE OF INVENTION

### Technical Problem

However, in the light detection apparatus disclosed in Patent Literature 1, stress may be caused in the wiring layer due to a difference in physical properties between wiring of the wiring layer and an interlayer insulation film in the logic substrate. Further, the sensor substrate including photoelectric converters may be affected by the stress, and this may result in a reduction in a level of imaging properties.

It is an object of the present disclosure to provide a light detection apparatus and an electronic apparatus that make it possible to prevent a reduction in a level of imaging properties.

### Solution to Problem

A light detection apparatus according to the present disclosure includes (a) a sensor substrate that includes a first semiconductor substrate on which a plurality of photoelectric converters is arranged; and (b) a logic substrate that includes a second semiconductor substrate to which a logic circuit is provided, and a first wiring layer that is stacked on the second semiconductor substrate, (c) the sensor substrate and the logic substrate are arranged in a layered formation such that the first wiring layer of the logic substrate faces the sensor substrate, (d) a second wiring layer that includes wiring and an insulator is formed inside of the second semiconductor substrate, the wiring extending in parallel with a first surface that is a surface of the second semiconductor substrate that is situated on a side of the first wiring layer, the insulator insulating the wiring from the second semiconductor substrate, and (e) the wiring in the second wiring layer is electrically connected to a specified portion of a connection target formed in the first surface of the second semiconductor substrate or a second surface of the second semiconductor substrate that is situated opposite to the first surface.

An electronic apparatus according to the present disclosure includes a light detection apparatus that includes (a) a sensor substrate that includes a first semiconductor substrate on which a plurality of photoelectric converters is arranged, and a logic substrate that includes (b) a second semiconductor substrate to which a logic circuit is provided, and (c) a first wiring layer that is stacked on the second semiconductor substrate, (d) the sensor substrate and the logic substrate are arranged in a layered formation such that the first wiring layer of the logic substrate faces the sensor substrate, (d) a second wiring layer that includes wiring and an insulator is formed inside of the second semiconductor substrate, the wiring extending in parallel with a first surface that is a surface of the second semiconductor substrate that is situated on a side of the first wiring layer, the insulator insulating the wiring from the second semiconductor substrate, and (e) the wiring in the second wiring layer is electrically connected to a specified portion of a connection target formed in the first surface of the second semiconductor substrate or a second surface of the second semiconductor substrate that is situated opposite to the first surface.

### BRIEF DESCRIPTION OF DRAWINGS

FIG. 1 illustrates a schematic configuration of the entirety of a solid-state imaging apparatus according to a first embodiment.

FIG. 2 illustrates a configuration of a cross section of the solid-state imaging apparatus along the line A-A illustrated in FIG. 1.

FIG. 3 illustrates a configuration of a cross section of a second semiconductor substrate.

FIG. 4A illustrates a method for forming a second wiring layer.

FIG. 4B illustrates the method for forming the second wiring layer.

FIG. 4C illustrates the method for forming the second wiring layer.

FIG. 4D illustrates the method for forming the second wiring layer.

FIG. 4E illustrates the method for forming the second wiring layer.

FIG. 4F illustrates the method for forming the second wiring layer.

FIG. 4G illustrates the method for forming the second wiring layer.

FIG. 4H illustrates the method for forming the second wiring layer.

FIG. 4I illustrates the method for forming the second wiring layer.

FIG. 5 illustrates a configuration of a cross section of the solid-state imaging apparatus according to a second embodiment.

FIG. 6A illustrates a method for forming the second wiring layer.

FIG. 6B illustrates the method for forming the second wiring layer.

FIG. 6C illustrates the method for forming the second wiring layer.

FIG. 6D illustrates the method for forming the second wiring layer.

FIG. 6E illustrates the method for forming the second wiring layer.

FIG. 6F illustrates the method for forming the second wiring layer.

FIG. 6G illustrates the method for forming the second wiring layer.

FIG. 6H illustrates the method for forming the second wiring layer.

FIG. 7 illustrates a configuration of a cross section of the solid-state imaging apparatus according to a modification (1).

FIG. 8 illustrates a configuration of a cross section of the solid-state imaging apparatus according to the modification (1).

FIG. 9 illustrates a configuration of a cross section of the solid-state imaging apparatus according to a modification (2).

FIG. 10 illustrates a configuration of a cross section of the solid-state imaging apparatus according to the modification (2).

FIG. 11 illustrates a configuration of a cross section of the solid-state imaging apparatus according to a modification (3).

FIG. 12 illustrates a configuration of a cross section of the solid-state imaging apparatus according to the modification (3).

FIG. 13 illustrates a configuration of a cross section of the solid-state imaging apparatus according to a modification (4).

FIG. 14 illustrates a configuration of a cross section of the solid-state imaging apparatus according to a modification (5).

FIG. 15 illustrates a schematic configuration of an electronic apparatus to which the present technology is applied.

### MODE(S) FOR CARRYING OUT THE INVENTION

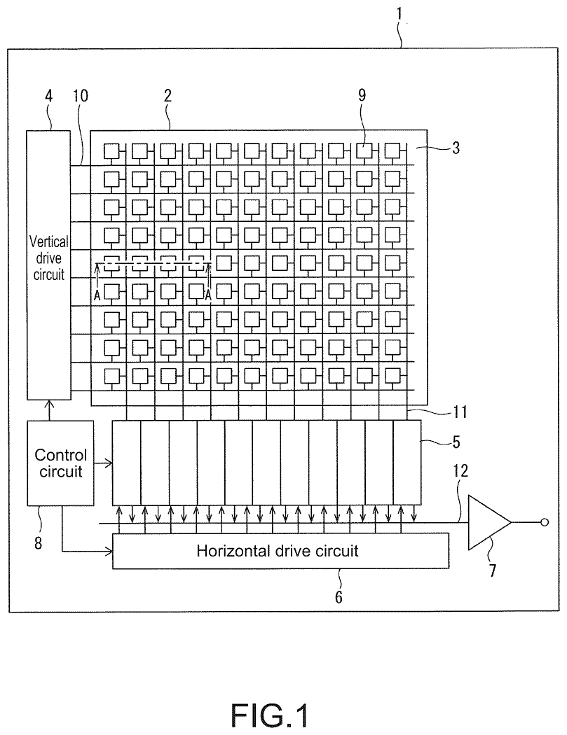

Examples of a light detection apparatus and an electronic apparatus according to embodiments of the present disclosure will be described below with reference to FIGS. 1 to 15. The embodiments of the present disclosure are described in the following order. Note that the present disclosure is not limited to examples described below. Further, the effects described herein are not limitative but are merely illustrative, and other effects may be provided.
1. First Embodiment: Solid-State Imaging Apparatus
1-1 Overall Configuration of Solid-State Imaging Apparatus
1-2 Configuration of Primary Portion
1-3 Method for Forming Second Wiring Layer
2. Second Embodiment: Solid-State Imaging Apparatus
2-1 Configuration of Primary Portion
2-2 Method for Forming Second Wiring Layer
2-3 Modifications
3. Electronic Apparatus

### 1. First Embodiment: Solid-State Imaging Apparatus

### [1-1 Overall Configuration of Solid-State Imaging Apparatus]

A solid-state imaging apparatus 1 according to a first embodiment of the present disclosure (a “light detection apparatus” in a broad sense) is described. FIG. 1 illustrates a schematic configuration of the entirety of the solid-state imaging apparatus 1 according to the first embodiment.

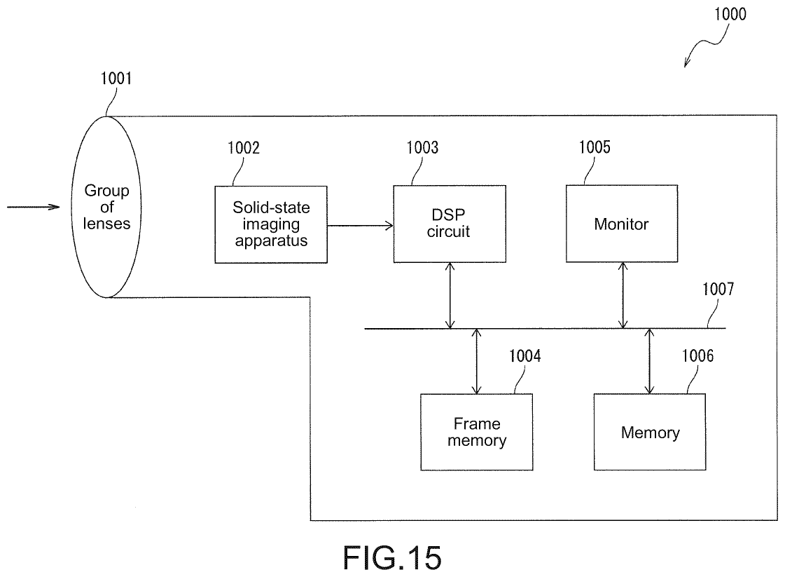

The solid-state imaging apparatus 1 illustrated in FIG. 1 is a backside-irradiation complementary metal-oxide semiconductor (CMOS) image sensor. As illustrated in FIG. 15, the solid-state imaging apparatus 1 (1002) captures, through a group 1001 of lenses, image light (incident light) coming from a subject, and converts, per pixel and into an electric signal, an amount of the incident light imaged on an imaging surface of the solid-state imaging apparatus, and outputs the electric signal as a pixel signal.

As illustrated in FIG. 1, the solid-state imaging apparatus 1 includes a substrate 2 (hereinafter also referred to as a “first semiconductor substrate 15”), the first semiconductor substrate 15, a pixel region 3, a vertical drive circuit 4, a column signal processing circuit 5, a horizontal drive circuit 6, an output circuit 7, and a control circuit 8.

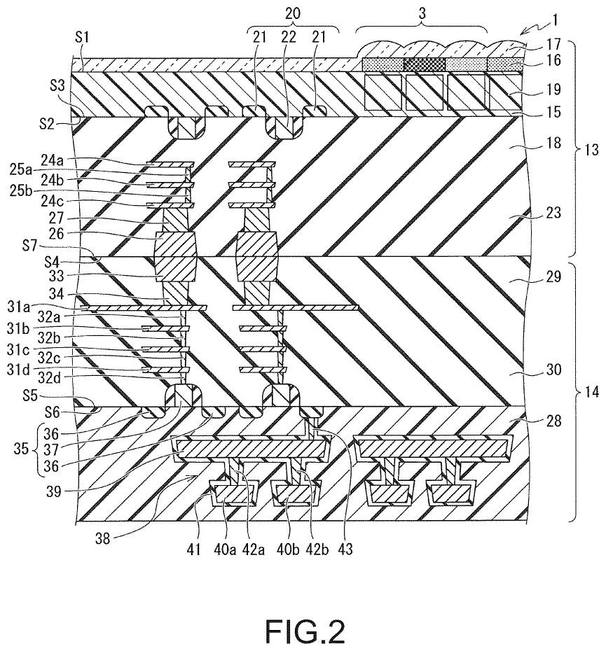

The pixel region 3 includes a plurality of pixels 9 arranged on the substrate 2 in a two-dimensional array. The pixel 9 includes a photoelectric converter 19 illustrated in FIG. 2, and a plurality of pixel transistors. For example, four transistors that include a transfer transistor, a reset transistor, an amplification transistor, and a selection transistor may be adopted as the plurality of pixel transistors.

The vertical drive circuit 4 includes, for example, a shift register, selects desired pixel drive wiring 10, and supplies a pulse used to drive the pixel 9 to the selected pixel drive wiring 10 to drive the pixels 9 for each row. In other words, the vertical drive circuit 4 vertically selectively scans the pixels 9 in the pixel region 3 successively for each row, and supplies the column signal processing circuit 5 with a pixel signal based on signal charges generated by the photoelectric converter 19 of each pixel 9 according to an amount of light received.

For example, the column signal processing circuit 5 is arranged for each column of the pixels 9, and performs signal processing such as denoising for each pixel column with respect to a signal output from the pixels 9 included in a row. For example, the column signal processing circuit 5 performs signal processing such as correlated double sampling (CDS) used to remove fixed-pattern noise specific to a pixel, and analog/digital (AD) conversion.

The horizontal drive circuit 6 includes, for example, a shift register, successively outputs a horizontally scanning pulse to the column signal processing circuit 5 to select the column signal processing circuits 5 in sequence, and causes a pixel signal on which signal processing has been performed to be output from each column signal processing circuit 5 to a horizontal signal line 12.

The output circuit 7 performs signal processing on pixel signals successively supplied by the respective column signal processing circuits 5 through the horizontal signal line 12, and outputs the pixel signals. For example, buffering, black level adjustment, correction for variation in column, and various digital signal processing may be used as the signal processing.

The control circuit 8 generates a clock signal and a control signal on the basis of a vertical synchronization signal, a horizontal synchronization signal, and a master clock signal, where, for example, the vertical drive circuit 4, the column signal processing circuit 5, and the horizontal drive circuit 6 operate on the basis of the clock signal and the control signal. Then, the control circuit 8 outputs the generated clock signal and control signal to, for example, the vertical drive circuit 4, the column signal processing circuit 5, and the horizontal drive circuit 6.

### [1-2 Configuration of Primary Portion]

Next, a detailed structure of the solid-state imaging apparatus 1 illustrated in FIG. 1 is described. FIG. 2 illustrates a configuration of a cross section of the solid-state imaging apparatus 1 along the line A-A illustrated in FIG. 1.

As illustrated in FIG. 2, the solid-state imaging apparatus 1 includes a sensor substrate 13 that includes the pixel region 3, and a logic substrate 14 that includes a logic circuit that performs various signal processing related to an operation of the solid-state imaging apparatus 1. For example, the logic substrate 14 includes, as the logic circuit, at least one of the vertical drive circuit 4, the column signal processing circuit 5, the horizontal drive circuit 6, the output circuit 7, or the control circuit 8 illustrated in FIG. 1. Note that the sensor substrate 13 may also include a portion of the logic circuit. The sensor substrate 13 and the logic substrate 14 are joined to each other by being arranged in a layered formation, such that a wiring layer 18 of the sensor substrate 13 and a first wiring layer 29 of the logic substrate 14 face each other.

The sensor substrate 13 includes a first semiconductor substrate 15, a color filter 16, and a microlens 17, where the color filter 16 and the microlens 17 are formed on a side of a light entrance surface (hereinafter also referred to as a “back surface S1”) of the first semiconductor substrate 15. Further, the sensor substrate 13 includes a wiring layer (hereinafter also referred to as the “wiring layer 18”) that is formed on a surface (hereinafter also referred to as a “front surface S2”) of the first semiconductor substrate 15 that is situated opposite to the back surface S1.

The first semiconductor substrate 15 includes, for example, a substrate made of silicon (Si), and forms the pixel region 3. The pixels 9 of a plurality of pixels 9 are arranged on the pixel region 3 in a two-dimensional array, each pixel 9 including the photoelectric converter 19 and pixel transistors (not illustrated). The photoelectric converter 19 includes a p-type semiconductor region and an n-type semiconductor region, and a photodiode is formed by a p-n junction. Consequently, each photoelectric converter 19 generates signal charges dependent on an amount of light incident on the photoelectric converter 19, and accumulates the generated signal charges in the n-type semiconductor region.

Further, a plurality of transistors 20 being a portion of the logic circuit may be formed on a side of the front surface S2 of the first semiconductor substrate 15. FIG. 2 illustrates an example in which the transistors 20 are formed outside of the pixel region 3. For example, a metal oxide semiconductor (MOS) transistor may be adopted as the transistor 20. The transistor 20 includes a pair of source and drain regions 21, and a gate electrode 22 that is formed on the front surface S2 through a gate insulation film.

The wiring layer 18 is formed on the side of the front surface S2 of the first semiconductor substrate 15, and includes an interlayer insulation film 23, pieces of wiring 24a, 24b, and 24c, and vias 25a and 25b. The pieces of wiring 24a, 24b, and 24c are arranged in a multilayered formation through the interlayer insulation film 23, and the pieces of wiring 24a, 24b, and 24c in different layers are electrically connected to each other by the vias 25a and 25b. Further, the wiring layer 18 includes a metal pad 26 and a connection conductor 27 on a side of a surface (hereinafter also referred to as a “front surface S4”) of the wiring layer 18 that is situated opposite to a surface S3 of the wiring layer 18 that is situated on a side of the first semiconductor substrate 15. A surface of the metal pad 26 is exposed from the interlayer insulation film 23, and the connection conductor 27 extends from the metal pad 26 to be connected to the wiring 24c.

The logic substrate 14 includes a second semiconductor substrate 28, and a wiring layer (hereinafter also referred to as a “first wiring layer 29”) that is stacked on a side of a light entrance surface (hereinafter also referred to as a “back surface S5”) of the second semiconductor substrate 28. In other words, the first wiring layer 29 is situated on a side of the sensor substrate 13.

The first wiring layer 29 includes an interlayer insulation film 30, pieces of wiring 31a, 31b, 31c, and 31d, and vias 32a, 32b, and 32c. The pieces of wiring 31a, 31b, 31c, and 31d are arranged in a multilayered formation through the interlayer insulation film 30, and the pieces of wiring 31a, 31b, 31c, and 31d in different layers are electrically connected to each other by the vias 32a, 32b, and 32c. Further, the wiring 31d is connected to a gate electrode 37 of a transistor 35 of the second semiconductor substrate 28 through a connection conductor 32d that extends in parallel with a direction of a thickness of the second semiconductor substrate 28. Further, the first wiring layer 29 includes a metal pad 33 and a connection conductor 34 on a side of a surface (hereinafter also referred to as a “front surface S7”) of the first wiring layer 29 that is situated opposite to a surface S6 of the first wiring layer 29 that is situated on a side of the second semiconductor substrate 28. A surface of the metal pad 33 is exposed from the interlayer insulation film 30, and the connection conductor 34 extends from the metal pad 33 to be connected to the wiring 31a.

Each metal pad 33 of the logic substrate 14 is arranged to face a corresponding metal pad 26 of the sensor substrate 13, and is directly joined to the facing metal pad 26. Consequently, the pieces of wiring 24a, 24b, and 24c of the wiring layer 18 of the sensor substrate 13 are electrically connected to the pieces of wiring 31a, 31b, 31c, and 31d of the wiring layer 18 of the logic substrate 14. Thus, an electric signal that is supplied through the pieces of wiring 24a, 24b, and 24c of the wiring layer 18 is input to the gate electrode 37 of the transistor 35 of the second semiconductor substrate 28.

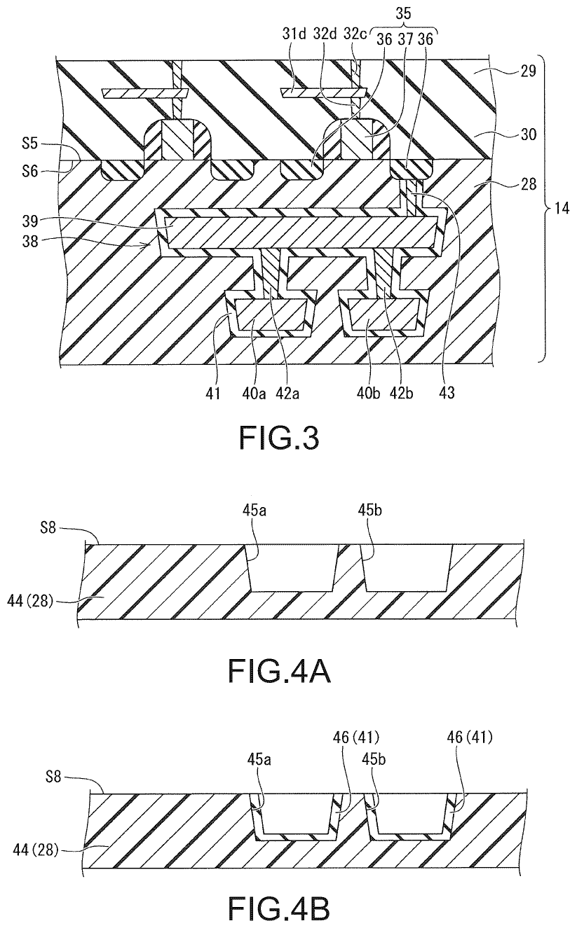

The second semiconductor substrate 28 includes a substrate made of, for example, silicon (Si). Further, a plurality of transistors 35 included in a logic circuit is formed on a side of the back surface S5 of the second semiconductor substrate 28, as illustrated in FIG. 3. For example, a MOS transistor may be adopted as the transistor 35. The transistor 35 includes a pair of n-type source and drain regions 36, and a gate electrode 37 that is formed through a gate insulation film.

Furthermore, a second wiring layer 38 is formed inside of the second semiconductor substrate 28. The second wiring layer 38 includes a plurality of pieces of wiring (hereinafter also referred to as “first wiring 39” and “second wiring 40a,40b”) and an insulator 41. The first wiring 39 and the second wiring 40a,40b each extend in parallel with the back surface S5 (a “first surface” in a broad sense) of the second semiconductor substrate 28. FIG. 3 illustrates an example in which the first wiring 39 extends in a row direction (a right-and-left direction in FIG. 3) and the second wiring 40a,40b extends in a column direction (a depth direction in FIG. 3). Further, the first wiring 39 and the second wiring 40a,40b are spaced in a layered formation in the direction of the thickness of the second semiconductor substrate 28. FIG. 3 illustrates an example in which the first wiring 39 is arranged in an upper layer and the second wiring 40a,40b is arranged in a lower layer to form a multilayered wiring layer that corresponds to the second wiring layer 38.

Further, the first wiring 39 (wiring in the upper layer) and the second wiring 40a,40b (wiring in the lower layer) are electrically connected to each other through a via 42a,42b. The via 42a,42b extends in parallel with the direction of the thickness of the second semiconductor substrate 28 (a direction that is orthogonal to the back surface S5). Furthermore, the area of a cross section of each of the first wiring 39 and the second wiring 40a,40b in a width direction (the area of a cross section of each of the first wiring 39 and the second wiring 40a,40b that is orthogonal to a longitudinal direction) is larger than the area of a cross section of each of the pieces of wiring 31a to 31c of the first wiring layer 29 in the width direction. For example, at least one of the condition that “a height of the cross section of each of the first wiring 39 and the second wiring 40a,40b in the width direction (the cross section orthogonal to the longitudinal direction)”>“a height of the cross section of each of the pieces of wiring 31a to 31c of the first wiring layer 29 in the width direction”, or the condition that “a width of the cross section of each of the first wiring 39 and the second wiring 40a, 40b in the width direction”>“a width of the cross section of each of the pieces of wiring 31a to 31c of the first wiring layer 29 in the width direction” is satisfied.

Further, the first wiring 39 and the second wiring 40a,40b serve as power supply wiring that is electrically connected to a power supply circuit that applies a power supply voltage to the transistor 35. FIG. 3 illustrates an example in which the first wiring 39 situated in an uppermost layer is electrically connected to the drain region 36 (a “specified portion of a connection target” in a broad sense) of the transistor 35 (the “connection target” in a broad sense) through a connection conductor 43 that extends in parallel with the direction of the thickness of the second semiconductor substrate 28. More specifically, the first wiring 39 illustrated in FIG. 3 is directly electrically connected to the drain region 36 only through the connection conductor 43 extending in parallel with the direction of the thickness of the second semiconductor substrate 28 toward the drain region 36 situated in the second semiconductor substrate 28 from the first wiring 39 situated in the second wiring layer 38. Here, the transistor 35 illustrated in FIG. 3 is assumed to be an n-type transistor. The connection conductor 43 is a connection conductor that extends in parallel with the direction of the thickness of the second semiconductor substrate 28 from the first wiring 39 toward the drain region 36 included in the transistor 35 and situated in the second semiconductor substrate 28.

Furthermore, for example, at least one of tungsten (W), copper (Cu), titanium (Ti), tantalum (Ta), cobalt (Co), or aluminum (Al) may be adopted as materials of the first wiring 39, the second wiring 40a,40b, the via 42a,42b, and the connection conductor 43.

Further, the insulator 41 is arranged between the first wiring 39 and the second semiconductor substrate 28, between the second wiring 40a,40b and the second semiconductor substrate 28, between the via 42a,42b and the second semiconductor substrate 28, and between the connection conductor 43 and the second semiconductor substrate 28 to insulate the first wiring 39, the second wiring 40a,40b, the via 42a,42b, and the connection conductor 43 from the second semiconductor substrate 28. FIG. 3 illustrates an example in which the insulator 41 is an insulation film that covers outer peripheral surfaces of the first wiring 39, the second wiring 40a,40b, the via 42a,42b and the connection conductor 43. For example, at least one of silicon oxide (SiO₂), silicon nitride (SiN), silicon oxynitride (SiON), or carbon-containing silicon oxide (SiOC) may be adopted as a material of the insulator 41.

Here, the inventors of the present disclosure have found out as a result of daily researches that, when an existing solid-state imaging apparatus 1 that includes power supply wiring arranged inside of the first wiring layer 29 is used, the power supply wiring may appear in an imaging result obtained by imaging performed by the solid-state imaging apparatus 1. Further, the inventors have conducted intensive researches on such appearance of the power supply wiring, and have found out the following. Since the power supply wiring is thick wiring that has a larger cross-sectional area in the width direction than other wiring, great stress is caused in the first wiring layer 29 along the power supply wiring, and the sensor substrate 13 is affected by the stress caused along the power supply wiring. This results in the power supply wiring appearing in the imaging result obtained by the imaging.

On the other hand, in the solid-state imaging apparatus 1 according to the first embodiment, the second wiring layer 38 is formed in the second semiconductor substrate 28. The first wiring 39 (wiring) and second wiring 40a,40b (wiring) extending in parallel with the back surface S5 (the first surface) of the second semiconductor substrate 28 are provided in the second wiring layer 38. Further, the insulator 41 insulating the first wiring 39 and the second wiring 40a,40b from the second semiconductor substrate 28 is provided. Furthermore, the first wiring 39 (the wiring) and the second wiring 40a,40b (the wiring) in the second wiring layer 38 are electrically connected to the drain region 36 (the specified portion) of the transistor 35 (the connection target) formed in the back surface S5 (the first surface) of the second semiconductor substrate 28.

Consequently, for example, thick wiring such as power supply wiring that applies a power supply voltage to the drain region 36 (the specified portion) of the transistor 35 (the connection target) can be arranged in the second wiring layer 38 as each of the first wiring 39 and the second wiring 40a,40b. Thus, for example, a distance between the sensor substrate 13 and thick wiring can be made larger, compared to when a method including arranging thick wiring in the first wiring layer 29 is adopted. This makes it possible to prevent the sensor substrate 13 from being affected by stress caused due to the thick wiring. This results in being able to prevent thick wiring (power supply wiring) from appearing in an imaging result obtained by imaging performed by the solid-state imaging apparatus 1. This makes it possible to provide the solid-state imaging apparatus 1 making it possible to prevent a reduction in a level of imaging properties.

Note that, when, for example, the area of a cross section of power supply wiring in the width direction is made small in order to prevent the power supply wiring from appearing, IR drop may occur in the power supply wiring. Consequently, there is a trade-off relationship between the appearance of the power supply wiring and the IR drop. This results in design limits.

On the other hand, in the solid-state imaging apparatus 1 according to the first embodiment, there is no need to make the area of a cross section of power supply wiring (the first wiring 39 and the second wiring 40a,40b) in the width direction smaller. This results in there being no need for design limits.

Further, in the solid-state imaging apparatus 1 according to the first embodiment, the first wiring 39 and the second wiring 40a,40b (a plurality of pieces of wiring) are spaced in a layered formation in the direction of the thickness of the second semiconductor substrate 28, and the first wiring 39 (wiring in an upper layer) and the second wiring 40a,40b (wiring in a lower layer) are connected to each other through the via 42a,42b to form a multilayered wiring layer corresponding to the second wiring layer 38. Furthermore, the insulator 41 includes insulation films 46, 47, 51, 52, and 55, and outer peripheral surfaces of the first wiring 39, the second wiring 40a,40b, and the via 42a,42b are covered with, for example, the insulation film 46. Consequently, there is only a need for a small region, in the second semiconductor substrate 28, that is to be occupied by the second wiring layer 38. This makes it possible to arrange a device such as a transistor on the side of the back surface S5 of the second semiconductor substrate 28 or on a side that is across the second wiring layer 38 from the back surface S5.

### [1-3 Method for Forming Second Wiring Layer]

Next, a method for forming the second wiring layer 38 is described.

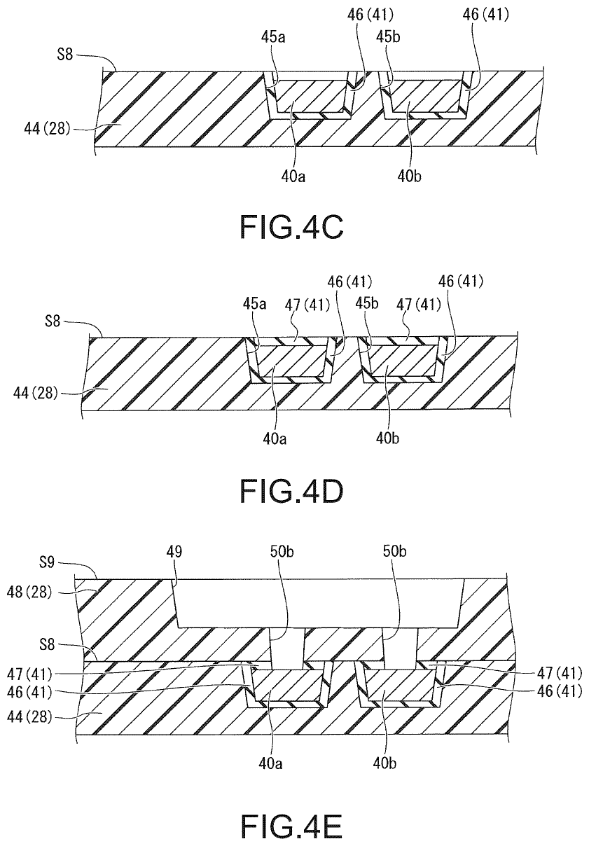

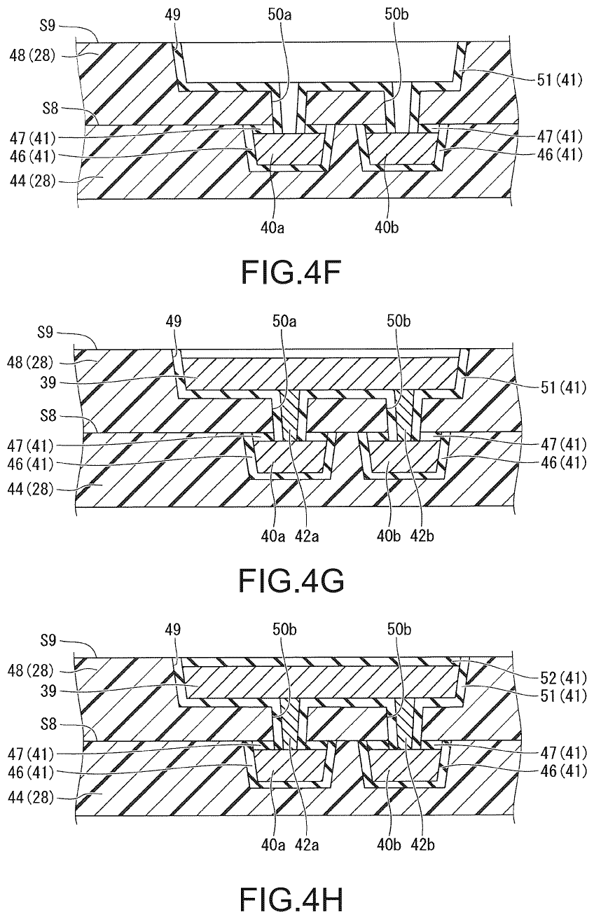

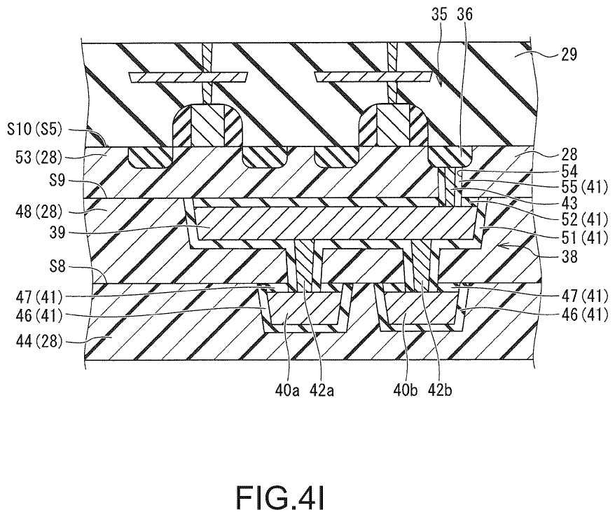

First, as illustrated in FIG. 4A, a fifth semiconductor substrate 44 is provided, and a trench 45a,45b is formed by etching in the fifth semiconductor substrate 44 from a side of one of surfaces (a side of a back surface S8) of the fifth semiconductor substrate 44. The trench 45a,45b is formed at a position that overlaps, in the plan view, a position at which the second wiring 40a,40b is to be formed. The fifth semiconductor substrate 44, a fourth semiconductor substrate 48 described later, and a third semiconductor substrate 53 described later are substrates that are included in the second semiconductor substrate 28. Subsequently, as illustrated in FIG. 4B, the insulation film 46 (for example, silicon oxide) is formed by, for example, CVD on an inner wall surface and a bottom surface of the formed trench 45a,45b. The insulation film 46 and insulation films 51, 52, and 55 described later are films that are included in the insulator 41. Subsequently, as illustrated in FIG. 4C, a film made of a material (for example, tungsten) of the second wiring 40a,40b is formed by, for example, CVD in the trench 45a,45b of which the inner wall surface and the bottom surface are covered with the insulation film 46. Accordingly, the second wiring 40a,40b is formed. Subsequently, as illustrated in FIG. 4D, the insulation film 47 (for example, silicon oxide) is formed by, for example, CVD on a side of an opening of the trench 45a,45b to cover around the second wiring 40a,40b with the insulation films 46 and 47. The insulation film 47 is a film included in the insulator 41.

Subsequently, as illustrated in FIG. 4E, the fourth semiconductor substrate 48 is stacked on the side of the back surface S8 of the fifth semiconductor substrate 44. Thereafter, a trench 49 is formed by etching in the fourth semiconductor substrate 48 from a side of an upper surface (a side of a back surface S9) of the fourth semiconductor substrate 48. The trench 49 is formed at a position that overlaps, in the plan view, a position at which the wiring layer 18 is to be formed. Subsequently, a through hole 50a,50b is formed by etching in the fourth semiconductor substrate 48 from a side of a bottom surface of the trench 49. The through hole 50a,50b is formed at a position that overlaps, in the plan view, a position at which the via 42a,42b is to be formed. The through hole 50a,50b is formed up to a depth at which the second wiring 40a,40b is exposed from a bottom surface of the through hole 50a,50b. Subsequently, as illustrated in FIG. 4F, the insulation film 51 (for example, silicon oxide) is formed by, for example, CVD on inner wall surfaces of the formed trench 49 and through hole 50a,50b. Subsequently, as illustrated in FIG. 4G, a film made of a material (for example, tungsten) of the first wiring 39 and the via 42a,42b is formed by, for example, CVD in the trench 49 and through hole 50a,50b of which the inner wall surfaces are covered with the insulation film 51. Accordingly, the first wiring 39 and the via 42a,42b are formed.

Subsequently, as illustrated in FIG. 4H, the insulation film 52 (for example, silicon oxide) is formed by, for example, CVD on a side of an opening of the trench 49 to cover the first wiring 39 with the insulation films 51 and 52.

Subsequently, as illustrated in FIG. 4I, the third semiconductor substrate 53 is stacked on the back surface S9 of the fourth semiconductor substrate 48. Thereafter, a through hole 54 is formed by etching in the third semiconductor substrate 53 from a side of an upper surface (a side of a back surface S10) of the third semiconductor substrate 53. The through hole 54 is formed at a position that overlaps, in the plan view, a position at which the connection conductor 43 is to be formed. The through hole 54 is formed up to a depth at which the first wiring 39 is exposed from a bottom surface of the through hole 54. Subsequently, the insulation film 55 is formed by, for example, CVD on an inner wall surface of the formed through hole 54. Subsequently, a film made of a material (for example, tungsten) of the connection conductor 43 is formed by, for example, CVD in the through hole 54 of which the inner wall surface is covered with the insulation film 55. Accordingly, the connection conductor 43 is formed. Subsequently, the transistor 35 included in a logic circuit is formed on the side of the back surface S10 of the third semiconductor substrate 53. The drain region 36 of the transistor 35 is electrically connected to an end of the connection conductor 43.

The second wiring layer 38 is formed by such a procedure.

### Second Embodiment: Solid-State Imaging Apparatus

### [2-1 Configuration of Primary Portion]

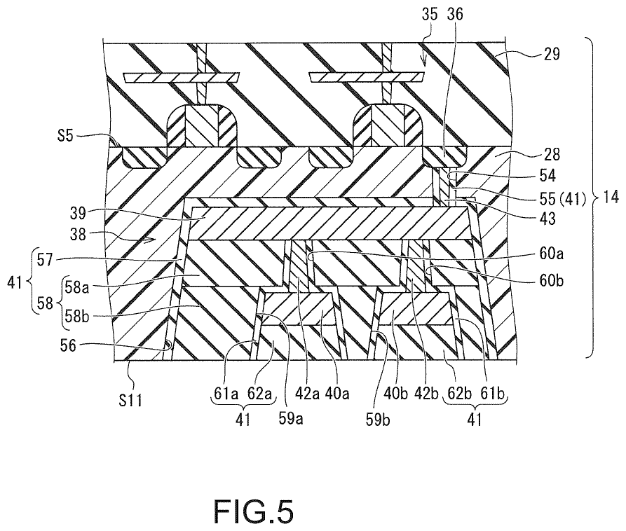

Next, the solid-state imaging apparatus 1 according to a second embodiment of the present disclosure is described. The solid-state imaging apparatus according to the second embodiment has an overall configuration that is similar to that of the solid-state imaging apparatus illustrated in FIG. 1. Thus, an illustration thereof is omitted. FIG. 5 illustrates a configuration of a cross section of a primary portion of the solid-state imaging apparatus 1 according to the second embodiment. A portion of the second embodiment that corresponds to a portion of the first embodiment is denoted by the same reference numeral as the portion of the first embodiment, and a repetitive description is omitted.

The solid-state imaging apparatus 1 according to the second embodiment includes the second wiring layer 38 having a configuration that is different from the configuration of the second wiring layer 38 included in the solid-state imaging apparatus 1 according to the first embodiment. In the second embodiment, a trench 56 is formed on a surface (hereinafter also referred to as a “front surface S11”) of the second semiconductor substrate 28 that is situated opposite to the back surface S5. The trench 56 is formed at a position that overlaps a position of the first wiring 39 in the plan view, as illustrated in FIG. 5. The first wiring 39 and insulator 41 being included in the second wiring layer 38 are arranged inside of the trench 56. The insulator 41 includes an insulation film 57 that covers an inner wall surface and a bottom surface of the trench 56, and an insulator 58 that is filled into the trench 56 of which the inner wall surface and the bottom surface are covered with the insulation film 57. The first wiring 39 is arranged at a bottom of the trench 56 through the insulation film 57, and is covered with the insulation film 57 and the insulator 58. An insulator 58a that is etched at a low speed is used as the insulator 58 on a side of the bottom of the trench 56 (at a depth at which the via 42a,42b is formed), and an insulator 58b that is etched at a high speed is used as the insulator 58 on a side of an opening of the trench 56. Examples of the insulators 58a and 58b include silicon nitride and silicon oxide.

Further, a trench 59a,59b is formed in the front surface S11 of the second semiconductor substrate 28. The trench 59a,59b is formed at a position that overlaps a position of the second wiring 40a,40b in the plan view. Further, a through hole 60a,60b is formed at a bottom surface of the trench 59a,59b. The through hole 60a,60b is formed at a position that overlaps, in the plan view, a position at which the via 42a,42b is to be formed. The through hole 60a,60b is formed up to a depth at which the through hole 60a, 60b reaches the first wiring 39. The second wiring 40a,40b, via 42a,42b, and insulator 41 being included in the second wiring layer 38 are arranged inside of the trench 59a,59b and through hole 60a,60b. The insulator 41 includes an insulation film 61a,61b that covers an inner wall surface and the bottom surface of the trench 59a,59b and an inner wall surface of the through hole 60a,60b, and an insulator 62a,62b that is filled into the trench 59a,59b of which the inner wall surface and the bottom surface are covered with the insulation film 61a,61b. Further, the second wiring 40a,40b is arranged at a bottom of the trench 59a,59b through the insulation film 61a,61b, and is covered with the insulation film 61a,61b and the insulator 58. Further, the via 42a,42b is arranged inside of the through hole 60a,60b, and is covered with the insulator 62a,62b.

Consequently, the solid-state imaging apparatus 1 according to the second embodiment has a configuration in which pieces of wiring of a plurality of pieces of wiring (the first wiring 39 and the second wiring 40a,40b) are spaced in a layered formation in the direction of the thickness of the second semiconductor substrate 28, and the piece of wiring in an upper layer (the first wiring 39) and the piece of wiring in a lower layer (the second wiring 40a,40b) are electrically connected to each other through the via 42a,42b to form the second wiring layer 38.

### [2-2 Method for Forming Second Wiring Layer]

Next, a method for forming the second wiring layer 38 is described.

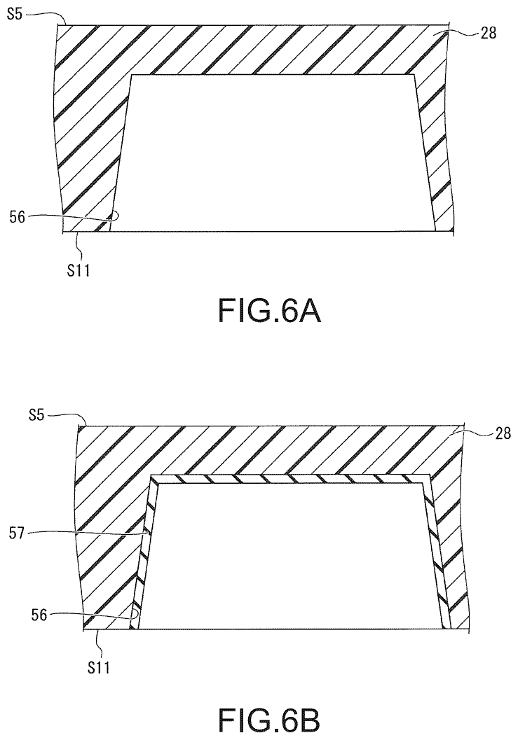

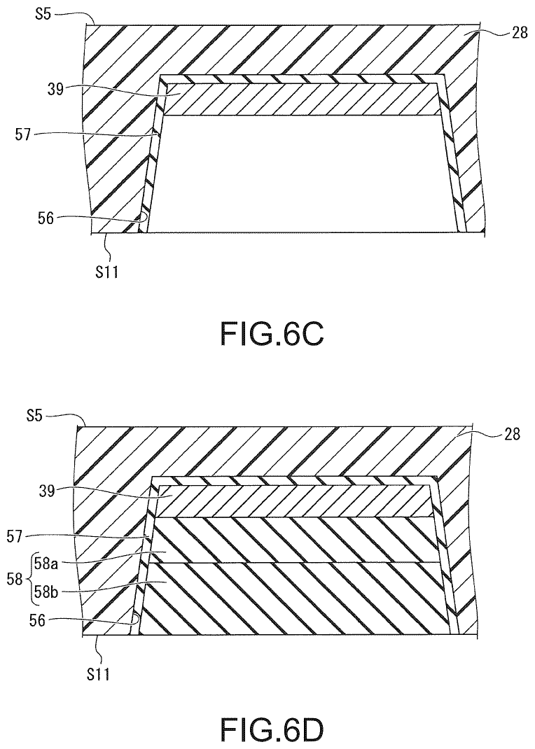

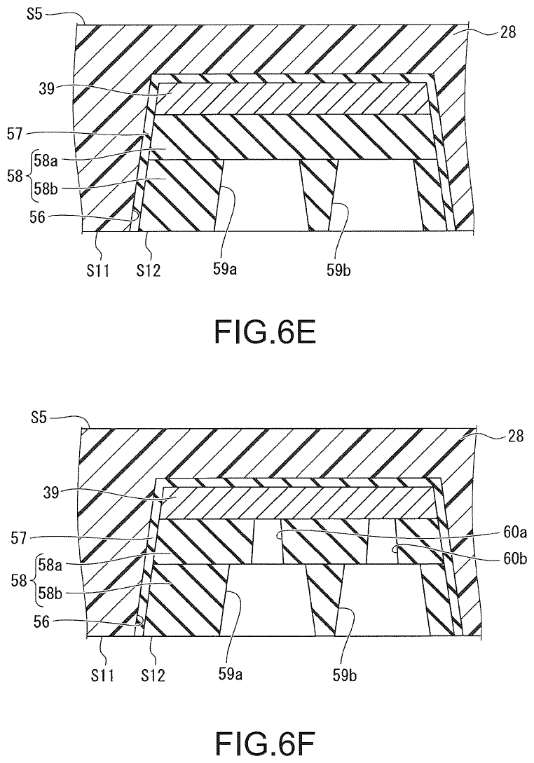

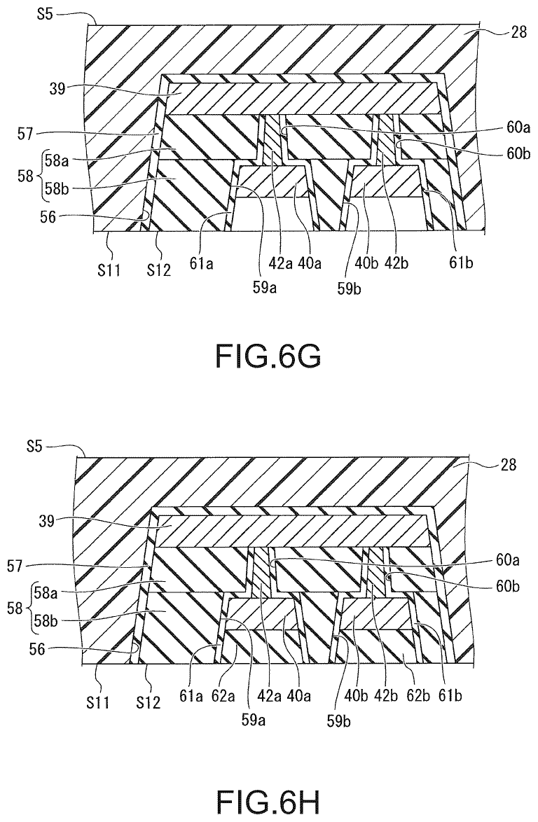

First, as illustrated in FIG. 6A, the second semiconductor substrate 28 is provided, and the trench 56 is formed by etching in the second semiconductor substrate 28 from a side of another of the surfaces (a side of the front surface S11) of the second semiconductor substrate 28. The trench 56 is formed at a position that overlaps, in the plan view, a position at which the first wiring 39 is to be formed. Subsequently, as illustrated in FIG. 6B, the insulation film 57 (for example, silicon oxide) is formed by, for example, CVD on the inner wall surface and the bottom surface of the formed trench 56. Subsequently, as illustrated in FIG. 6C, a film made of a material (for example, tungsten) of the first wiring 39 is formed by, for example, CVD on the portion being situated at the bottom inside of the trench 56 and covered with the insulation film 57. Accordingly, the first wiring 39 is formed.

Subsequently, as illustrated in FIG. 6D, the insulator 58 (the insulator 58a,58b) is filled by, for example, CVD into the remaining portion in the trench 56, that is, a portion situated closer to an opening of the trench 56 than the first wiring 39. Subsequently, as illustrated in FIG. 6E, the trench 59a,59b is formed in the insulator 58 from a surface on a side of a front surface S12 of the insulator 58. The trench 59a,59b is formed at a position that overlaps, in the plan view, a position at which the second wiring 40a,40b is to be formed. Subsequently, as illustrated in FIG. 6F, the through hole 60a,60b is formed by etching in the insulator 58 from a side of the bottom surface of the trench 59a,59b. The through hole 60a, 60b is formed at a position that overlaps, in the plan view, a position at which the via 42a,42b is to be formed. The through hole 60a,60b is formed up to a depth at which the first wiring 39 is exposed from a bottom surface of the through hole 60a,60b.

Subsequently, as illustrated in FIG. 6G, the insulation film 61a,61b (for example, silicon oxide) is formed by, for example, CVD on the inner wall surfaces of the trench 59a,59b and the through hole 60a,60b. Subsequently, a film made of a material (for example, tungsten) of the second wiring 40a,40b and the via 42a,42b is formed by, for example, CVD in a portion of the trench 59a,59b that is situated on the side of the bottom surface of the trench 59a,59b and in the through hole 60a,60b to form the second wiring 40a,40b and the via 42a,42b. Subsequently, as illustrated in FIG. 6H, the insulator 62a,62b (for example, silicon oxide) is formed by, for example, CVD in a portion of the trench 59a,59b that is situated on a side of an opening of the trench 59a,59b to cover the second wiring 40a,40b with the insulator 62a,62b.

Subsequently, as illustrated in FIG. 5, the through hole 54 is formed by etching in the second semiconductor substrate 28 from the side of the back surface S5 of the second semiconductor substrate 28. The through hole 54 is formed at a position that overlaps, in the plan view, a position at which the connection conductor 43 is to be formed. The through hole 54 is formed up to a depth at which the first wiring 39 is exposed from the bottom surface of the through hole 54. Subsequently, the insulation film 55 is formed by, for example, CVD on the inner wall surface of the formed through hole 54. Subsequently, a film made of a material (for example, tungsten) of the connection conductor 43 is formed by, for example, CVD in the through hole 54 of which the inner wall surface is covered with the insulation film 55. Accordingly, the connection conductor 43 is formed. Subsequently, the transistor 35 included in a logic circuit is formed on the side of the back surface S5 of the second semiconductor substrate 28. The drain region 36 of the transistor 35 is electrically connected to an end of the connection conductor 43.

The second wiring layer 38 is formed by such a procedure.

In the solid-state imaging apparatus 1 according to the second embodiment, the trenches 56, 59a, and 59b are formed in the front surface S11 (a second surface) of the second semiconductor substrate 28, as described above. Further, the insulator 41 corresponds to the insulation films 57, 61a, and 61b covering the inner wall surfaces and bottom surfaces of the trenches 56, 59a, and 59b; and the insulators 58, 62a, and 62b arranged in the trenches 56, 59a, and 59b. Further, pieces of wiring in the second wiring layer 38 are arranged at the bottoms of the trenches 56, 59a, and 59b through the insulation films 57, 61a, and 61b to be covered with the insulation films 57, 61a, and 61b and with the insulators 58, 62a, and 62b arranged in the trenches 56, 59a, and 59b. This results in obtaining a relatively simple configuration having a single semiconductor substrate serving as the second semiconductor substrate 28.

### [2-3 Modifications]

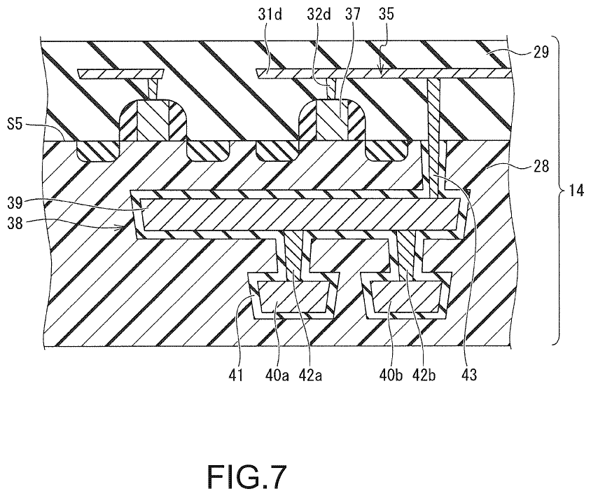

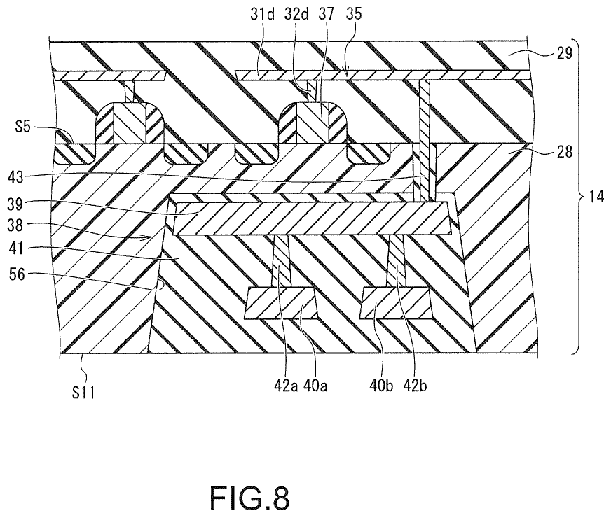

(1) Note that the example in which the first wiring 39 is connected to the drain region 36 of the transistor 35 has been described in the first and second embodiments. However, any other configurations may be adopted. For example, a configuration in which the first wiring 39 is connected to the gate electrode 37 of the transistor 35, as illustrated in FIGS. 7 and 8, may be adopted. FIG. 7 illustrates an example in which such a configuration is applied to the solid-state imaging apparatus 1 according to the first embodiment. Further, FIG. 8 illustrates an example in which such a configuration is applied to the solid-state imaging apparatus 1 according to the second embodiment. FIGS. 7 and 8 each illustrate the first wiring 39 being electrically connected to the gate electrode 37 through the connection conductor 43 (a “first connection conductor” in a broad sense), the wiring 31d situated in the first wiring layer 29, and the connection conductor 32d (a “second connection conductor” in a broad sense), where the connection conductor 43 extends in parallel with the direction of the thickness of the second semiconductor substrate 28 toward the wiring 31d situated in the first wiring layer 29 from the first wiring 39 situated in the second wiring layer 38, and the connection conductor 32d extends in parallel with the direction of the thickness of the second semiconductor substrate 28 toward the gate electrode 37 (the specified portion) of the transistor 35 from the wiring 31d situated in the first wiring layer 29. When the configuration in which the first wiring 39 is connected to the gate electrode 37 is adopted, the first wiring 39 and the second wiring 40a,40b may be pieces of signal wiring that supply various signals.

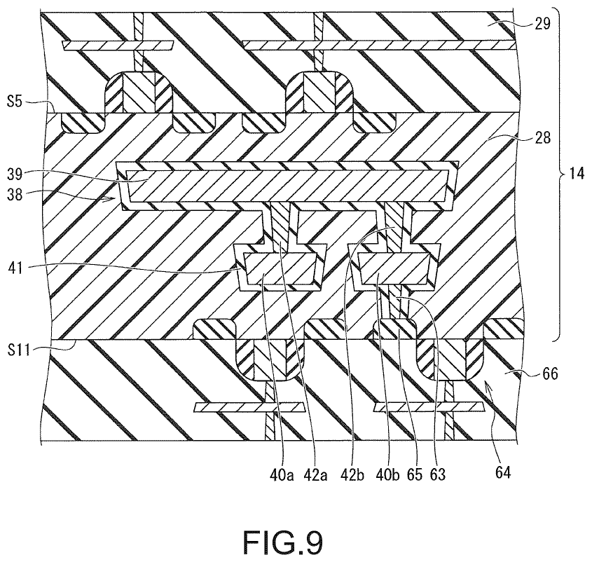

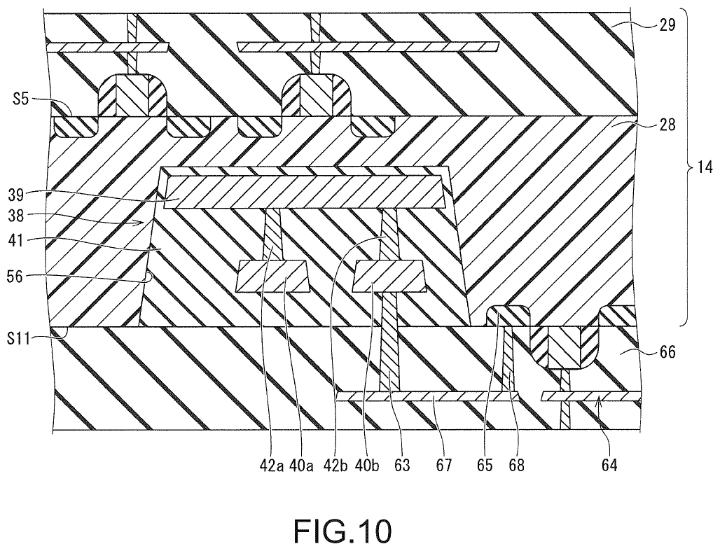

(2) Further, for example, a configuration in which pieces of wiring (the first wiring 39 and the second wiring 40a,40b) situated in the second semiconductor substrate 28 are connected to, for example, a drain region or a gate electrode of a transistor that is formed in the front surface S11 (the second surface) of the second semiconductor substrate 28, or wiring of a wiring layer (the specified portion of the connection target), as illustrated in FIGS. 9 and 10, may be adopted. FIG. 9 illustrates an example in which such a configuration is applied to the solid-state imaging apparatus 1 according to the first embodiment. Further, FIG. 10 illustrates an example in which such a configuration is applied to the solid-state imaging apparatus 1 according to the second embodiment. FIG. 9 illustrates an example in which the second wiring 40b situated in the second semiconductor substrate 28 is electrically connected to a drain region 65 of a transistor 64 through a connection conductor 63 that extends in parallel with the direction of the thickness of the second semiconductor substrate 28, the transistor 64 being formed on the side of the front surface S11 of the second semiconductor substrate 28. Further, FIG. 10 illustrates an example in which the second wiring 40b is electrically connected to the drain region 65 of the transistor 64 through the connection conductor 63, wiring 67, and a connection conductor 68, the wiring 67 being situated in a third wiring layer 66 that is formed on the side of the front surface S11 of the second semiconductor substrate 28.

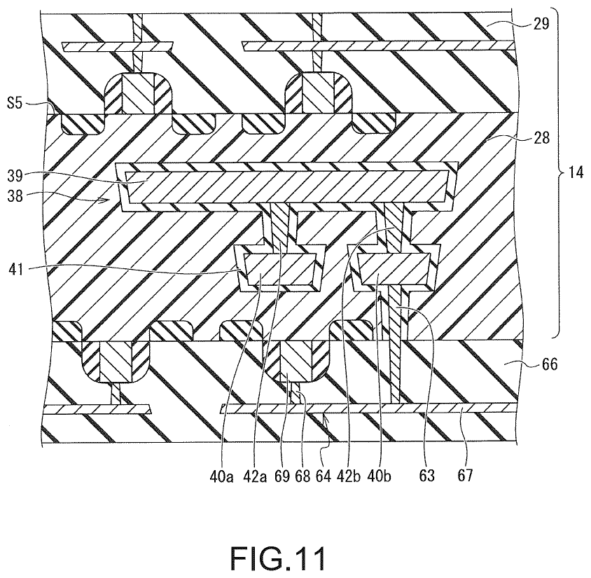

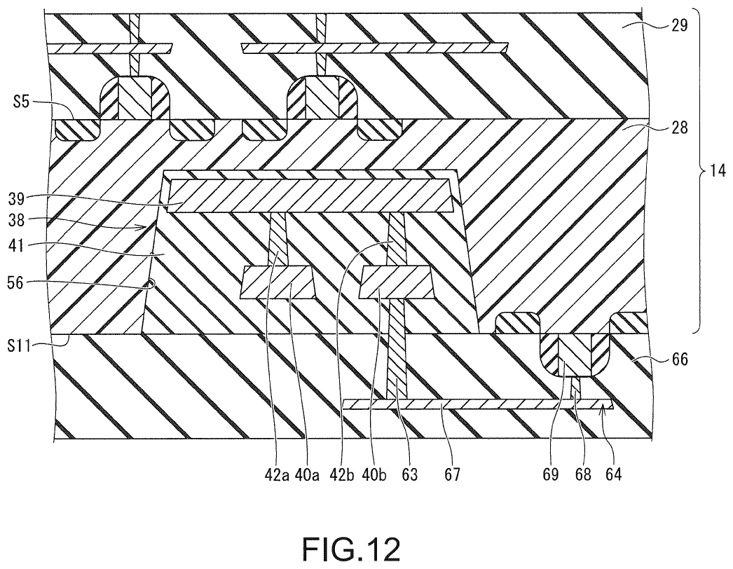

(3) Further, for example, a configuration in which the pieces of wiring situated in the second semiconductor substrate 28 are connected to a gate electrode 69 of the transistor 64, as illustrated in FIGS. 11 and 12, may be adopted. FIG. 11 illustrates an example in which such a configuration is applied to the solid-state imaging apparatus 1 according to the first embodiment. Further, FIG. 12 illustrates an example in which such a configuration is applied to the solid-state imaging apparatus 1 according to the second embodiment. FIGS. 11 and 12 each illustrate an example in which the second wiring 40b is electrically connected to the gate electrode 69 through the connection conductor 63 (the “first connection conductor” in a broad sense), the wiring 67 situated in the third wiring layer 66, and the connection conductor 68 (the “second connection conductor” in a broad sense), where the connection conductor 43 extends in parallel with the direction of the thickness of the second semiconductor substrate 28 toward the wiring 67 situated in the third wiring layer 66 formed on the front surface S11 of the second semiconductor substrate 28 from the second wiring 40b situated in the second wiring layer 38, and the connection conductor 68 extends in parallel with the direction of the thickness of the second semiconductor substrate 28 toward the gate electrode 69 (the specified portion) of the transistor 64 from the wiring 67 situated in the third wiring layer 66.

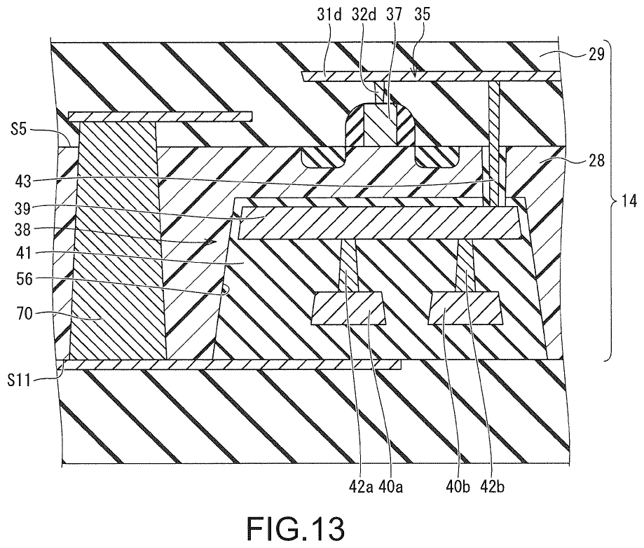

(4) Further, the example in which the second wiring layer 38 and the transistor 35 are arranged in the second semiconductor substrate 28 has been described in the first and second embodiments. However, any other configurations may be adopted. For example, a configuration in which a throug-silicon via (TSV, a through-silicon electrode) that passes through the second semiconductor substrate 28 is further provided in a region that is included in the second semiconductor substrate 28 and in which the second wiring layer 38 is not formed, as illustrated in FIG. 13, may be adopted. FIG. 13 illustrates an example in which the TSV 70 is applied to the modification (1) of the solid-state imaging apparatus 1 according to the second embodiment illustrated in FIG. 8.

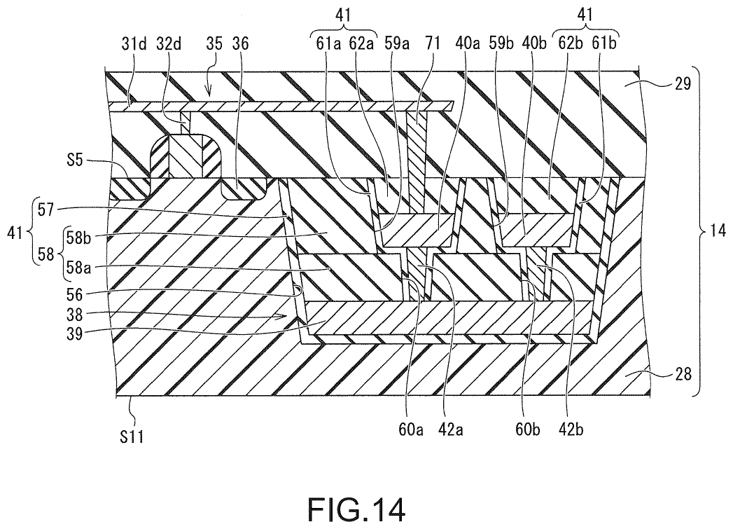

(5) Further, the example in which the trench 56 of the second semiconductor substrate 28 is formed in the front surface S11 (the second surface) of the second semiconductor substrate 28 has been described in the second embodiment. However, any other configurations may be adopted. For example, a configuration in which the trench 56 is formed in the back surface S5 (the first surface) of the second semiconductor substrate 28, as illustrated in FIG. 14, may be adopted. In this case, the transistor 35 is arranged in a region that does not overlap, in the plan view, a region in which the trench 56 is formed. FIG. 14 illustrates an example in which the first wiring 39 is situated on the side of the front surface S11 and the second wiring 40a,40b is situated on the side of the back surface S5. FIG. 14 illustrates an example in which the second wiring 40a is electrically connected to the drain region 36 of the transistor 35 through a connection conductor 71, the wiring 31d situated in the first wiring layer 29, and the connection conductor 32d, the connection conductor 71 extending in parallel with the direction of the thickness of the second semiconductor substrate 28.

(6) Further, the present technology can be applied to not only the above-described solid-state imaging apparatus serving as an image sensor, but also all of light detection apparatuses including a ranging sensor that measures a distance and is also called a time-of-flight (ToF) sensor. The ranging sensor is a sensor that emits irradiation light toward an object, detects reflected light that is the irradiation light returning by being reflected off the surface of the object, and calculates a distance to the object on the basis of the time of flight from the irradiation light being emitted to the reflected light being received. The structure of the second wiring layer 38 described above may be adopted as a wiring structure of the ranging sensor.

### <3. Electronic Apparatus>

The technology according to the present disclosure (the present technology) may be applied to various electronic apparatuses.

FIG. 15 illustrates an example of a schematic configuration of an image-capturing apparatus 1000 (such as a video camera or a digital still camera) that is an electronic apparatus to which the present technology is applied. As illustrated in FIG. 15, the image-capturing apparatus 1000 includes the group 1001 of lenses, the solid-state imaging apparatus 1002, a digital signal processor (DSP) circuit 1003, a frame memory 1004, a monitor 1005, and a memory 1006. The DSP circuit 1003, the frame memory 1004, the monitor 1005, and the memory 1006 are connected to each other through a bus line 1007.

The group 1001 of lenses guides, to the solid-state imaging apparatus 1002, incident light (image light) coming from a subject, and images the light on a light-receiving surface (a pixel region) of the solid-state imaging apparatus 1002.

The solid-state imaging apparatus 1002 is the above-described solid-state imaging apparatus of the first embodiment. The solid-state imaging apparatus 1002 converts, per pixel and into an electric signal, an amount of the incident light imaged on the light-receiving surface by the group 1001 of lenses, and supplies the electric signal to the DSP circuit 1003 as a pixel signal.

The DSP circuit 1003 performs specified image processing on the pixel signal supplied by the solid-state imaging apparatus 1002. Then, for each frame, the DSP circuit 1003 supplies the frame memory 1004 with the image signal on which the image processing has been performed, and causes the image signal to be temporarily stored in the frame memory 1004.

The monitor 1005 is a panel display apparatus such as a liquid crystal panel or an organic electroluminescence (EL) panel. The monitor 1005 displays thereon an image (for example, a moving image) of the subject on the basis of the pixel signal per frame temporarily stored in the frame memory 1004.

The memory 1006 is, for example, a DVD or a flash memory. The memory 1006 reads the pixel signal per frame temporarily stored in the frame memory 1004, and records therein the read pixel signal.

Note that the electronic apparatus to which the present technology can be applied is not limited to the image-capturing apparatus 1000. The present technology can also be applied to any other electronic apparatuses. Further, the example in which the solid-state imaging apparatus 1 according to the first embodiment is used as the solid-state imaging apparatus 1002 has been described. However, any other configurations may be adopted. For example, any other light detection apparatuses such as the solid-state imaging apparatus 1 according to the second embodiment and the solid-state imaging apparatuses 1 according to the modifications of the first and second embodiments to which the present technology is applied may be used.

Note that the present technology may also take the following configurations.

(1) A light detection apparatus, including:
a sensor substrate that includes a first semiconductor substrate on which a plurality of photoelectric converters is arranged; and
a logic substrate that includes
   a second semiconductor substrate to which a logic circuit is provided, and
   a first wiring layer that is stacked on the second semiconductor substrate, the sensor substrate and the logic substrate being arranged in a layered formation such that the first wiring layer of the logic substrate faces the sensor substrate, in which
a second wiring layer that includes wiring and an insulator is formed inside of the second semiconductor substrate, the wiring extending in parallel with a first surface that is a surface of the second semiconductor substrate that is situated on a side of the first wiring layer, the insulator insulating the wiring from the second semiconductor substrate, and the wiring in the second wiring layer is electrically connected to a specified portion of a connection target formed in the first surface of the second semiconductor substrate or a second surface of the second semiconductor substrate that is situated opposite to the first surface.
   (2) The light detection apparatus according to (1), in which
the wiring in the second wiring layer has a larger cross-sectional area in a width direction than wiring situated in the first wiring layer.
   (3) The light detection apparatus according to (1) or (2), in which
the wiring in the second wiring layer is power supply wiring that applies a power supply voltage to the connection target.
   (4) The light detection apparatus according to any one of (1) to (3), in which
the wiring in the second wiring layer is electrically connected to the specified portion through a connection conductor that extends in parallel with a direction of a thickness of the second semiconductor substrate.
   (5) The light detection apparatus according to (4), in which
the wiring in the second wiring layer is electrically connected to the specified portion through a first connection conductor, wiring situated in the first wiring layer, and a second connection conductor, the first connection conductor being the connection conductor extending in parallel with the thickness direction toward the wiring in the first wiring layer from the wiring in the second wiring layer, the second connection conductor extending in parallel with the thickness direction toward the specified portion from the wiring in the first wiring layer, or
the wiring in the second wiring layer is electrically connected to the specified portion through a first connection conductor, wiring situated in a third wiring layer that is formed on the second surface, and a second connection conductor, the first connection conductor being the connection conductor extending in parallel with the thickness direction toward the wiring in the third wiring layer from the wiring in the second wiring layer, the second connection conductor extending in parallel with the thickness direction toward the specified portion from the wiring in the third wiring layer.
   (6) The light detection apparatus according to (4), in which
the wiring in the second wiring layer is directly electrically connected to the specified portion only through the connection conductor extending in parallel with the direction of the thickness of the second semiconductor substrate toward the specified portion situated in the second semiconductor substrate from the wiring in the second wiring layer.
   (7) The light detection apparatus according to any one of (1) to (6), in which
the second wiring layer is a multilayered wiring layer in which the pieces of wiring of a plurality of the pieces of wiring are spaced in a layered formation in the direction of the thickness of the second semiconductor substrate, and the piece of wiring in an upper layer and the piece of wiring in a lower layer are connected to each other through a via.
   (8) The light detection apparatus according to any one of (1) to (7), in which
a material of the insulator is at least one of silicon oxide, silicon nitride, silicon oxynitride, or carbon-containing silicon oxide.
   (9) The light detection apparatus according to any one of (1) to (8), in which
a material of the wiring is at least one of tungsten, copper, titanium, tantalum, cobalt, or aluminum.
   (10) An electronic apparatus, including
a light detection apparatus that includes
   a sensor substrate that includes a first semiconductor substrate on which a plurality of photoelectric converters is arranged, and
   a logic substrate that includes
      a second semiconductor substrate to which a logic circuit is provided, and
      a first wiring layer that is stacked on the second semiconductor substrate, the sensor substrate and the logic substrate being arranged in a layered formation such that the first wiring layer of the logic substrate faces the sensor substrate, in which
a second wiring layer that includes wiring and an insulator is formed inside of the second semiconductor substrate, the wiring extending in parallel with a first surface that is a surface of the second semiconductor substrate that is situated on a side of the first wiring layer, the insulator insulating the wiring from the second semiconductor substrate, and
the wiring in the second wiring layer is electrically connected to a specified portion of a connection target formed in the first surface of the second semiconductor substrate or a second surface of the second semiconductor substrate that is situated opposite to the first surface.

### REFERENCE SIGNS LIST

1 solid-state imaging apparatus
2 substrate
3 pixel region
4 vertical drive circuit
5 column signal processing circuit
6 horizontal drive circuit
7 output circuit
8 control circuit
9 pixel
pixel drive wiring
11 vertical signal line
12 horizontal signal line
13 sensor substrate
14 logic substrate
first semiconductor substrate
16 color filter
17 microlens
18 wiring layer
19 photoelectric converter
transistor
21 source and drain regions
22 gate electrode
23 interlayer insulation film
24a. 24b. 24c wiring
25a, 25b via
26 metal pad
27 connection conductor
28 second semiconductor substrate
29 first wiring layer
30 interlayer insulation film
31a, 31b, 31c, 31d wiring
32a, 32b, 32c via
32d connection conductor
33 metal pad
34 connection conductor
35 transistor
36 source and drain regions
37 gate electrode
38 second wiring layer
39 first wiring
40a, 40b second wiring
41 insulator
42a. 42b via
43 connection conductor
44 fifth semiconductor substrate
45a. 45b trench
46 insulation film
47 insulation film
48 fourth semiconductor substrate
49 trench
50a. 50b through hole
51, 52 insulation film
53 third semiconductor substrate
54 through hole
55 insulation film
56 trench
57 insulation film
58 insulator
58a insulator
58b insulator
59a, 59b trench
60a, 60b through hole
61a, 61b insulation film
62a, 62b insulator
63 connection conductor
64 transistor
65 drain region
66 third wiring layer
67 wiring
68 connection conductor
69 gate electrode

What is claimed is:

1. A light detection apparatus, comprising:
a sensor substrate that includes a first semiconductor substrate on which a plurality of photoelectric converters is arranged; and
a logic substrate that includes
a second semiconductor substrate to which a logic circuit is provided, and
a first wiring layer that is stacked on the second semiconductor substrate,
the sensor substrate and the logic substrate being arranged in a layered formation such that the first wiring layer of the logic substrate faces the sensor substrate, wherein
a second wiring layer that includes wiring and an insulator is formed inside of the second semiconductor substrate, the wiring extending in parallel with a first surface that is a surface of the second semiconductor substrate that is situated on a side of the first wiring layer, the insulator insulating the wiring from the second semiconductor substrate, and
the wiring in the second wiring layer is electrically connected to a specified portion of a connection target formed in the first surface of the second semiconductor substrate or a second surface of the second semiconductor substrate that is situated opposite to the first surface.

2. The light detection apparatus according to claim 1, wherein
the wiring in the second wiring layer has a larger cross-sectional area in a width direction than wiring situated in the first wiring layer.

3. The light detection apparatus according to claim 1, wherein
the wiring in the second wiring layer is power supply wiring that applies a power supply voltage to the connection target.

4. The light detection apparatus according to claim 1, wherein
the wiring in the second wiring layer is electrically connected to the specified portion through a connection conductor that extends in parallel with a direction of a thickness of the second semiconductor substrate.

5. The light detection apparatus according to claim 4, wherein
the wiring in the second wiring layer is electrically connected to the specified portion through a first connection conductor, wiring situated in the first wiring layer, and a second connection conductor, the first connection conductor being the connection conductor extending in parallel with the thickness direction toward the wiring in the first wiring layer from the wiring in the second wiring layer, the second connection conductor extending in parallel with the thickness direction toward the specified portion from the wiring in the first wiring layer, or
the wiring in the second wiring layer is electrically connected to the specified portion through a first connection conductor, wiring situated in a third wiring layer that is formed on the second surface, and a second connection conductor, the first connection conductor being the connection conductor extending in parallel with the thickness direction toward the wiring in the third wiring layer from the wiring in the second wiring layer, the second connection conductor extending in parallel with the thickness direction toward the specified portion from the wiring in the third wiring layer.

6. The light detection apparatus according to claim 4, wherein
the wiring in the second wiring layer is directly electrically connected to the specified portion only through the connection conductor extending in parallel with the direction of the thickness of the second semiconductor substrate toward the specified portion situated in the second semiconductor substrate from the wiring in the second wiring layer.

7. The light detection apparatus according to claim 1, wherein
the second wiring layer is a multilayered wiring layer in which the pieces of wiring of a plurality of the pieces of wiring are spaced in a layered formation in the direction of the thickness of the second semiconductor substrate, and the piece of wiring in an upper layer and the piece of wiring in a lower layer are connected to each other through a via.

8. The light detection apparatus according to claim 1, wherein
a material of the insulator is at least one of silicon oxide, silicon nitride, silicon oxynitride, or carbon-containing silicon oxide.

9. The light detection apparatus according to claim 1, wherein
a material of the wiring is at least one of tungsten, copper, titanium, tantalum, cobalt, or aluminum.

10. An electronic apparatus, comprising
a light detection apparatus that includes
a sensor substrate that includes a first semiconductor substrate on which a plurality of photoelectric converters is arranged, and
a logic substrate that includes
a second semiconductor substrate to which a logic circuit is provided, and
a first wiring layer that is stacked on the second semiconductor substrate,
the sensor substrate and the logic substrate being arranged in a layered formation such that the first wiring layer of the logic substrate faces the sensor substrate, wherein
a second wiring layer that includes wiring and an insulator is formed inside of the second semiconductor substrate, the wiring extending in parallel with a first surface that is a surface of the second semiconductor substrate that is situated on a side of the first wiring layer, the insulator insulating the wiring from the second semiconductor substrate, and
the wiring in the second wiring layer is electrically connected to a specified portion of a connection target formed in the first surface of the second semiconductor substrate or a second surface of the second semiconductor substrate that is situated opposite to the first surface.
